(19) United States
(12) Patent Application Publication
(10) Pub. No.: US 2025/0201533 A1
(43) Pub. Date: Jun. 19, 2025

(54) PLASMA PROCESSING APPARATUS

(71) Applicant: Tokyo Electron Limited, Tokyo (JP)

(72) Inventor: Masaki HIRAYAMA, Fuchu City, Tokyo (JP)

(21) Appl. No.: 19/055,131

(22) Filed: Feb. 17, 2025

Related U.S. Application Data
(63) Continuation of application No. PCT/JP2023/029465, filed on Aug. 14, 2023.

(30) Foreign Application Priority Data
Aug. 25, 2022 (JP) 2022-134051

(51) Int. Cl. H01J 37/32

(52) U.S. Cl. CPC H01J 37/32568; H01J 37/32834; H01J 2237/327

(57) ABSTRACT

A plasma processing apparatus includes: a chamber including an inner wall surface; an introduction portion configured to introduce electromagnetic waves for plasma generation into the chamber; a choke configured to suppress the electromagnetic waves from propagating downward along the inner wall surface, and including a dielectric member, an upper conductor including a portion of the inner wall surface and extending above the dielectric member, and a lower conductor extending below the dielectric member; at least one first conductor electrically connected to the upper conductor; and at least one second conductor electrically connected to the lower conductor and extending below the first conductor, wherein the first conductor and the second conductor provide a gap between the first conductor and the second conductor at a location along an inner end of the dielectric member, the gap having a length in a vertical direction shorter than a thickness of the dielectric member.

### CROSS-REFERENCE TO RELATED APPLICATION

This application is a bypass continuation application of international application No. PCT/JP2023/029465 having an international filing date of Aug. 14, 2023 and designating the United States, the international application being based upon and claiming the benefit of priority from Japanese Patent Application No. 2022-134051, filed on Aug. 25, 2022, the entire contents of which are incorporated herein by reference.

### TECHNICAL FIELD

The present disclosure relates to a plasma processing apparatus.

### BACKGROUND

A plasma processing apparatus is used in plasma processing for a substrate. One type of plasma processing apparatus includes a chamber, a substrate support, an upper electrode, and an electromagnetic wave emission port. The chamber provides a processing space. The substrate support is provided in the processing space. The upper electrode is provided above the substrate support and configured to inject a gas into the processing space. The electromagnetic wave emission port is configured to introduce electromagnetic waves into the processing space from around the upper electrode. Such a plasma processing apparatus is introduced in Patent Document 1.

### PRIOR ART DOCUMENTS

### Patent Documents

Patent Document 1: Japanese Laid-Open Publication No. 2021-96934

### SUMMARY

According to one embodiment of the present disclosure, there is provided a plasma processing apparatus including: a chamber including an inner wall surface; an introduction portion configured to introduce electromagnetic waves for plasma generation into the chamber; a choke configured to suppress the electromagnetic waves from propagating downward along the inner wall surface, and including a dielectric member, an upper conductor including a portion of the inner wall surface and extending above the dielectric member, and a lower conductor extending below the dielectric member; at least one first conductor electrically connected to the upper conductor; and at least one second conductor electrically connected to the lower conductor and extending below the at least one first conductor, wherein the at least one first conductor and the at least one second conductor provide a gap between the at least one first conductor and the at least one second conductor at a location along an inner end of the dielectric member, the gap having a length in a vertical direction shorter than a thickness of the dielectric member.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram schematically showing a plasma processing apparatus according to one example embodiment.

FIG. 2 is a cross-sectional view of the plasma processing apparatus according to one example embodiment.

FIG. 3 is a partial enlarged perspective view of the plasma processing apparatus according to one example embodiment.

FIG. 4 is a partial enlarged cross-sectional view of the plasma processing apparatus according to one example embodiment.

FIG. 5 is a partial enlarged perspective view of a plasma processing apparatus according to another example embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Various example embodiments will now be described in detail with reference to the drawings, in which the same or corresponding components are designated by the same reference numerals.

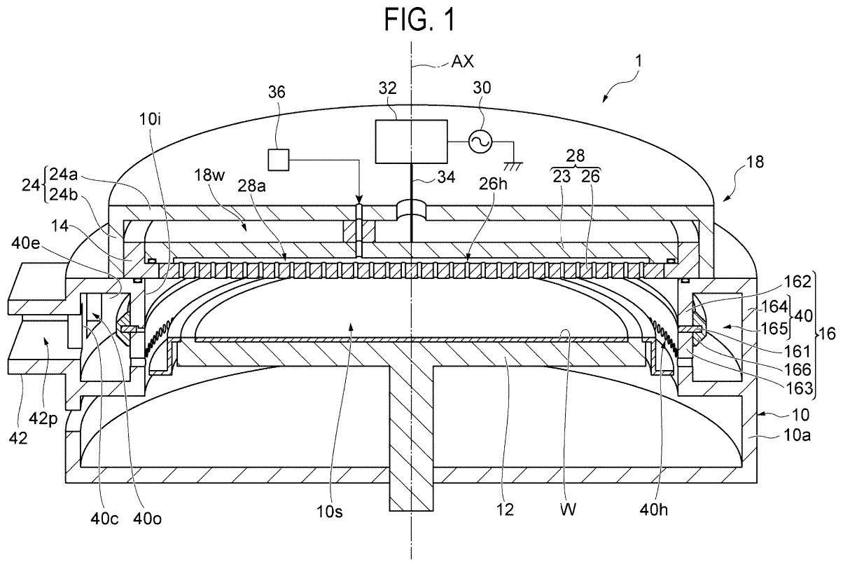

FIG. 1 is a diagram schematically showing a plasma processing apparatus according to one example embodiment. The plasma processing apparatus 1 shown in FIG. 1 includes a chamber 10, an introduction portion 14, a choke 16, a plurality of first conductors 21, and a plurality of second conductors 22.

The chamber 10 includes an inner wall surface 10i. The chamber 10 provides a processing space 10s therein. The inner wall surface 10i defines the processing space 10s. The inner wall surface 10i is provided by a side wall 10a of the chamber 10. In the plasma processing apparatus 1, the substrate W is processed in the processing space 10s. The chamber 10 is made of a metal such as aluminum and is grounded. The chamber 10 may have a substantially cylindrical shape with an opening at its upper end. A central axis of each of the chamber 10 and the processing space 10s is an axis AX. The chamber 10 may include a corrosion-resistant film on its surface. The corrosion-resistant film may be an yttrium oxide film, an yttrium oxide fluoride film, an yttrium fluoride film, or a ceramic film containing yttrium oxide, yttrium fluoride, or the like.

The plasma processing apparatus 1 may further include a substrate support 12. The substrate support 12 is provided in the processing space 10s. The substrate support 12 is configured to approximately horizontally support the substrate W mounted on its upper surface. The substrate support 12 is approximately formed in a disk shape. A central axis of the substrate support 12 is the axis AX.

The introduction portion 14 is provided so that electromagnetic waves are introduced into the chamber 10 in order to generate plasma in the chamber 10. The introduction portion 14 is made of a dielectric material such as quartz, aluminum nitride, or aluminum oxide. The introduction portion 14 may be approximately formed in an annular shape, and a central axis thereof may be the axis AX. The electromagnetic waves introduced into the chamber 10 from the introduction portion 14 are radio-frequency waves such as VHF waves or UHF waves. The electromagnetic waves are generated by a radio-frequency power source described later. The electromagnetic waves propagate to the introduction portion 14 through a waveguide 18, and are introduced from the introduction portion 14 into the chamber 10.

The waveguide 18 provides a waveguide path 18w. In one embodiment, the waveguide 18 may include an upper electrode 23 and an upper wall 24. The upper electrode 23 is provided above the substrate support 12. The upper electrode 23 is made of a conductor such as aluminum or the like, and is approximately formed in a disk shape. A central axis of the upper electrode 23 is the axis AX.

The upper wall 24 is made of a conductor such as aluminum or the like. The upper wall 24 is provided so as to cover the upper electrode 23. A waveguide path 18w is formed between the upper electrode 23 and the upper wall 24. The upper wall 24 may include an upper portion 24a and a side portion 24b. The upper portion 24a is approximately formed in a disk shape, and a central axis thereof is the axis AX. The upper portion 24a extends parallel to an upper surface of the upper electrode 23 above the upper electrode 23. The waveguide path 18w is formed between the upper surface of the upper electrode 23 and a lower surface of the upper portion 24a of the upper wall 24. The side portion 24b is approximately formed in a cylindrical shape, and a central axis thereof is the axis AX. The side portion 24b extends downward from a peripheral edge of the upper portion 24a. The introduction portion 14 is provided so as to fill a space between an inner circumferential surface of the side portion 24b and an outer circumferential surface of the upper electrode 23. Further, the upper wall 24 may be arranged above the side wall 10a of the chamber 10 such that a lower end of the side portion 24b contacts the side wall 10a.

The plasma processing apparatus 1 further includes a radio-frequency power source 30 and a matcher 32. The radio-frequency power source 30 is configured to generate radio-frequency power. The electromagnetic waves to be introduced into the chamber 10 are generated based on the radio-frequency power generated by the radio-frequency power source 30. The radio-frequency power source 30 is connected to the upper electrode 23 via the matcher 32 and an electric line 34. The matcher 32 includes a matching circuit for matching a load impedance of the radio-frequency power source 30 to an output impedance of the radio-frequency power source 30. The electric line 34 extends downward from the matcher 32 and is connected to a center of the upper surface of the upper electrode 23. The electric line 34 may extend along the axis AX.

In one embodiment, the plasma processing apparatus 1 may further include a shower plate 26. The shower plate 26 is provided above the substrate support 12. The shower plate 26 is approximately formed in a disk shape. A central axis of the shower plate 26 is the axis AX. The shower plate 26 may be made of a conductor such as aluminum or the like. A space between an outer circumferential surface of the shower plate 26 and the inner circumferential surface of the side portion 24b of the upper wall 24 is filled with the introduction portion 14. The introduction portion 14 and the shower plate 26 are provided to close the opening at the upper end of the chamber 10.

The shower plate 26 provides a plurality of gas holes 26h. The gas holes 26h penetrate the shower plate 26 in a plate thickness direction and are opened toward the processing space 10s. The upper electrode 23 is provided over the shower plate 26. The upper electrode 23 and the shower plate 26 constitute a shower head 28. The upper electrode 23 and the shower plate 26 form a gas diffusion space 28a therebetween. The gas holes 26h extend downward from the gas diffusion space 28a.

A gas supplier 36 is connected to the gas diffusion space 28a. A gas outputted from the gas supplier 36 is supplied to the processing space 10s via the gas diffusion space 28a and the plurality of gas holes 26h. The gas supplied by the gas supplier 36 is selected according to the processing to be performed in the processing space 10s. The gas supplied by the gas supplier 36 may include a film-forming gas. The gas supplied by the gas supplier 36 may include a cleaning gas used for cleaning the wall surface in the chamber 10.

In the plasma processing apparatus 1, the electromagnetic waves introduced into the chamber 10 from the introduction portion 14 propagate along a lower surface of the shower plate 26. The electromagnetic waves generate plasma from the gas discharged from the shower plate 26 into the processing space 10s.

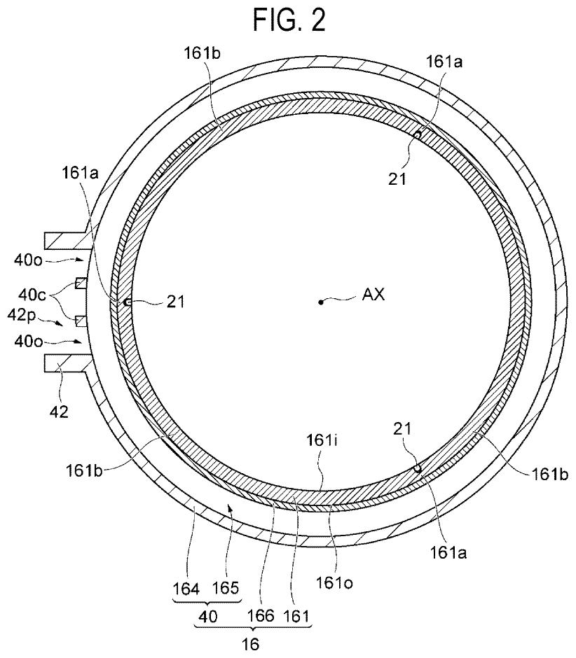

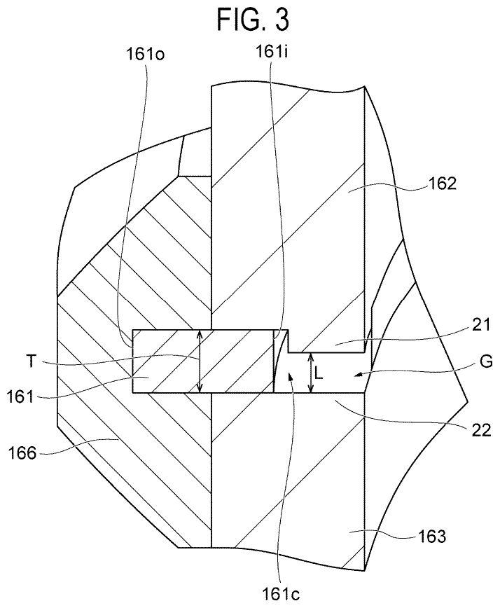

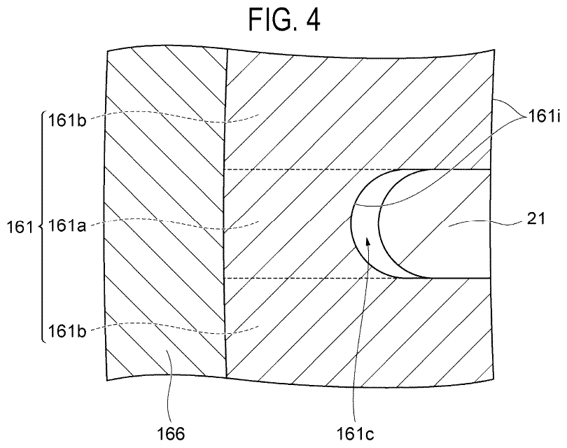

Hereinafter, reference is made to FIGS. 2 to 4 in addition to FIG. 1. FIG. 2 is a cross-sectional view of the plasma processing apparatus according to one example embodiment. FIG. 2 shows a horizontal cross-sectional structure of a portion of the plasma processing apparatus 1 including the choke 16 and the plurality of first conductors 21. FIG. 3 is a partial enlarged perspective view of the plasma processing apparatus according to one example embodiment. FIG. 4 is a partial enlarged cross-sectional view of the plasma processing apparatus according to one example embodiment. FIG. 4 shows, on an enlarged scale, a horizontal cross-sectional structure of a portion of the plasma processing apparatus 1 including the choke 16 and one first conductor 21.

As shown in FIGS. 1 to 4, the plasma processing apparatus 1 includes the choke 16. The choke 16 is configured to suppress downward propagation of the electromagnetic waves along the inner wall surface 10i. The choke 16 includes a dielectric member 161, an upper conductor 162, and a lower conductor 163.

The upper conductor 162 includes a portion of the inner wall surface 10i and extends above the dielectric member 161. The upper conductor 162 may be a portion of the side wall 10a of the chamber 10. The lower conductor 163 extends below the dielectric member 161. The lower conductor 163 may include another portion of the inner wall surface 10i or may be a portion of the side wall 10a of the chamber 10. The upper conductor 162 and the lower conductor 163 provide a slit therebetween.

The dielectric member 161 is made of a dielectric material such as quartz, aluminum oxide, yttria, silicon carbide, or aluminum nitride. At least a portion of the dielectric member 161 is disposed in the above-mentioned slit. In one embodiment, the dielectric member 161 may be a plate having a ring shape, and may be disposed between the upper conductor 162 and the lower conductor 163 such that a central axis of the dielectric member 161 is located along the axis AX. As shown in FIGS. 2 to 4, the dielectric member 161 includes an inner end 161i and an outer end 1610. The inner end 161i is located closer to a center of the chamber 10 than the outer end 1610 is. That is, the inner end 161i is located closer to the axis AX than the outer end 161o is.

As shown in FIG. 1, the choke 16 may further provide a cavity 165 surrounded by a conductor 164. The cavity 165 may extend in a circumferential direction around the axis AX. The outer end 1610 of the dielectric member 161 may protrude into the cavity 165. That is, the outer end 161o of the dielectric member 161 may be disposed in the cavity 165. The dielectric member 161 and the cavity 165 are designed so that an impedance of the choke 16 to the electromagnetic waves is high. That is, the dielectric member 161 and the cavity 165 are designed so that parallel resonance of the electromagnetic waves occurs in the choke 16.

The choke 16 may further include an insulating member 166. The insulating member 166 is made of an insulator such as quartz, aluminum oxide, yttria, silicon carbide, aluminum nitride, or polytetrafluoroethylene. The insulating member 166 is provided so as to cover the dielectric member 161 in the cavity 165. In the plasma processing apparatus 1, intensity of an electric field of the electromagnetic waves in the cavity 165 is reduced by the insulating member 166.

In one embodiment, the conductor 164 and the cavity 165 may constitute an exhaust duct 40. In this embodiment, the exhaust duct 40 may include the upper conductor 162 and the lower conductor 163. That is, the conductor part may include the upper conductor 162 and the lower conductor 163 as its portion. The exhaust duct 40 may be an annular exhaust duct that provides the cavity 165 as an annular exhaust path, and may extend in the circumferential direction with respect to the axis AX.

An inner wall (or an inner circumferential wall) of the exhaust duct 40, i.e., the lower conductor 163, provides a plurality of through-holes 40h. The through-holes 40h are arranged in the circumferential direction with respect to the axis AX. The cavity 165 communicates with the processing space 10s via the through-holes 40h.

An outer wall 40e (or an outer circumferential wall) of the exhaust duct 40 provides an opening 40o. Another exhaust duct 42 is connected to the exhaust duct 40. The exhaust duct 42 provides an exhaust path 42p. The exhaust duct 42 and the exhaust path 42p extend away from the chamber 10, for example, in a radial direction with respect to the axis AX. The exhaust path 42p is connected to the cavity 165 via the opening 40o. In addition, an exhauster is connected to the exhaust duct 42. The exhauster may include a vacuum pump such as a dry pump and/or a turbo molecular pump, and an automatic pressure control valve.

A short-circuit portion 40c is provided in the opening 40o. The short-circuit portion 40c is made of a conductor such as aluminum or the like and has, for example, a rod shape. The short-circuit portion 40c electrically connects a pair of edges that define the opening 40o, i.e., an upper edge and a lower edge, to each other. The short-circuit portion 40c divides the opening 400 into a plurality of portions. A length of each of the portions of the opening 40o along the circumferential direction may be set to a length of 1/10 or less of the wavelength of the electromagnetic waves in the cavity 165. The short-circuit portion 40c allows the outer wall 40e to function as a short-circuit surface for the electromagnetic waves even in the portion where the opening 40p is provided.

As described above, the plasma processing apparatus 1 includes a plurality of first conductors 21 and a plurality of second conductors 22. In the example shown in FIGS. 1 to 4, each of the number of the first conductors 21 and the number of the second conductors 22 is three.

The plurality of first conductors 21 are made of a conductor such as aluminum or the like and are electrically connected to the upper conductor 162. As shown in FIG. 2, the plurality of first conductors 21 may be arranged at equal intervals along the circumferential direction around the axis AX. The plurality of second conductors 22 are made of a conductor such as aluminum or the like and are electrically connected to the lower conductor 163. The plurality of second conductors 22 may be arranged at equal intervals along the circumferential direction around the axis AX. As shown in FIG. 3, the plurality of second conductors 22 are respectively provided below the plurality of first conductors 21.

Each of the plurality of first conductors 21 and the second conductor 22 located below it among the plurality of second conductors 22 provide a gap G therebetween at a location along the inner end 161i of the dielectric member 161, the gap G having a vertical length L shorter than a thickness T of the dielectric member 161. The vertical length L of the gap G may be equal to or less than twice a thickness of a plasma sheath. The thickness of the plasma sheath is, for example, 0.6 mm or less. It is possible for the gap G having such a length to suppress intrusion of plasma into the gap G. The vertical length L of the gap G may be approximately twice the thickness of the plasma sheath. In this case, plasma is more likely to be ignited in the vicinity of the gap G.

In one embodiment, the plurality of first conductors 21 may be portions of the upper conductor 162. That is, the plurality of first conductors 21 and the upper conductor 162 may be formed from a single conductor wall. Furthermore, the plurality of second conductors 22 may be portions of the lower conductor 163. That is, the second conductors 22 and the lower conductor 163 may be formed from a single conductor wall.

As shown in FIGS. 3 and 4, in one embodiment, the inner end 161i of the dielectric member 161 may provide a plurality of notches 161c. The plurality of notches 161c may be arranged at equal intervals along the circumferential direction around the axis AX. The plurality of first conductors 21 may be fitted into the plurality of notches 161c, respectively. This suppresses displacement of the dielectric member 161 in the chamber 10. In this case, the gap G is provided in the corresponding notch 161c among the plurality of notches 161c. Both or one of each of the first conductors 21 and the corresponding second conductor 22 may be disposed in the corresponding notch 161c.

As shown in FIGS. 3 and 4, a space may be provided between the first conductor 21 and the inner end 161i of the dielectric member 161. In this case, even if thermal expansion of the conductor wall surrounding the dielectric member 161 occurs, application of stress to the dielectric member 161 is suppressed.

The dielectric member 161 may include a plurality of first portions 161a and a plurality of second portions 161b. The plurality of first portions 161a and the plurality of second portions 161b are alternately arranged along the circumferential direction. The plurality of first portions 161a are respectively located outside the plurality of notches 161c along the plurality of notches 161c. In the plurality of second portions 161b, the inner end 161i of the dielectric member 161 is continuous with each of an inner surface (or inner circumferential surface) of the upper conductor 162 and an inner surface (or inner circumferential surface) of the lower conductor 163, and constitutes a part of the inner wall surface 10i. In this embodiment, the inner end 161i of the dielectric member 161 in the first portions 161a extends further outward relative to the center of the chamber 10 compared to the inner end 161i of the dielectric member 161 in the second portions 161b.

In the plasma processing apparatus 1 described above, electric field intensity in a region near the gap G in the processing space 10s is increased by the plurality of first conductors 21 and the plurality of second conductors 22. Therefore, even if reflection of the electromagnetic waves is large, it is possible to ignite the plasma in the region near the gap G.

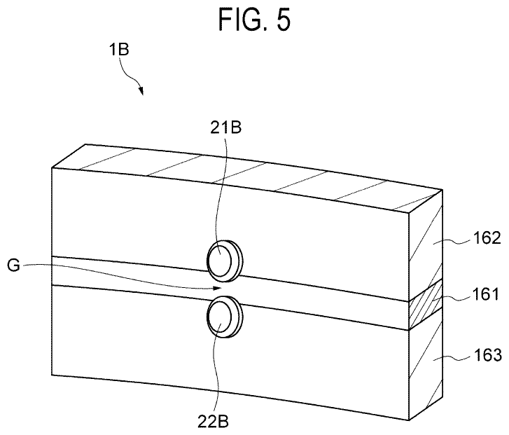

Hereinafter, reference is made to FIG. 5. FIG. 5 is a partial enlarged perspective view of a plasma processing apparatus according to another example embodiment of the present disclosure. The plasma processing apparatus 1B shown in FIG. 5 is described below from the viewpoint of differences between the plasma processing apparatus 1 and the plasma processing apparatus 1B.

The plasma processing apparatus 1B includes a plurality of first conductors 21B and a plurality of second conductors 22B. The plurality of first conductors 21B are made of a conductor such as aluminum or the like and are electrically connected to the upper conductor 162. The plurality of first conductors 21B may be arranged at equal intervals along the circumferential direction around the axis AX. The plurality of first conductors 21B protrude from the upper conductor 162 to an inside of the chamber 10. The plurality of first conductors 21B may be members separate from the upper conductor 162. For example, the plurality of first conductors 21B may be heads of a plurality of screws threadedly coupled to a plurality of screw holes formed at the upper conductor 162.

The plurality of second conductors 22B are made of a conductor such as aluminum or the like and are electrically connected to the lower conductor 163. The plurality of second conductors 22B may be arranged at equal intervals along the circumferential direction around the axis AX. The plurality of second conductors 22B are provided below the plurality of first conductors 21B. The plurality of second conductors 22B protrude from the lower conductor 163 toward the inside of the chamber 10. The plurality of second conductors 22B may be members separate from the lower conductor 163. For example, the plurality of second conductors 22B may be heads of screws threadedly coupled to screw holes formed in the lower conductor 163.

Each of the plurality of first conductors 21B and the second conductor 22B located below it among the plurality of second conductors 22B provide a gap G therebetween at a location along the inner end 161i of the dielectric member 161, the gap G having a vertical length shorter than the thickness of the dielectric member 161. The vertical length of the gap G may be equal to or less than twice the thickness of the plasma sheath. The thickness of the plasma sheath is, for example, equal to or less than 0.6 mm. The vertical length of the gap G may be approximately equal to or less than twice the thickness of the plasma sheath.

Although various example embodiments have been described above, the present disclosure is not limited to the above-described example embodiments, and various additions, omissions, substitutions, and modifications may be made. In addition, elements in different embodiments may be combined to form other embodiments.

For example, in a plasma processing apparatus according to yet another embodiment, the number of first conductors and the number of second conductors may be equal to or greater than one.

Various example embodiments included in the present disclosure are now described in [E1] to [E10] below.
[E1] A plasma processing apparatus, including:
   a chamber including an inner wall surface;
   an introduction portion configured to introduce electromagnetic waves for plasma generation into the chamber;
   a choke configured to suppress the electromagnetic waves from propagating downward along the inner wall surface, and including a dielectric member, an upper conductor including a portion of the inner wall surface and extending above the dielectric member, and a lower conductor extending below the dielectric member;
   at least one first conductor electrically connected to the upper conductor; and
   at least one second conductor electrically connected to the lower conductor and extending below the at least one first conductor,
   wherein the at least one first conductor and the at least one second conductor provide a gap between the at least one first conductor and the at least one second conductor at a location along an inner end of the dielectric member, the gap having a length in a vertical direction shorter than a thickness of the dielectric member.
[E2] The plasma processing apparatus of E1, wherein the dielectric member includes a first portion extending along the gap and a second portion other than the first portion, and
wherein an inner end of the second portion is continuous with each of an inner surface of the upper conductor and an inner surface of the lower conductor, and constitutes a portion of the inner wall surface.
[E3] The plasma processing apparatus of E2, wherein an inner end of the first portion extends further outward relative to a center of the chamber compared to the inner end of the second portion.
[E4] The plasma processing apparatus of any one of E1 to E3, wherein the at least one first conductor is a portion of the upper conductor, and wherein the at least one second conductor is a portion of the lower conductor.
[E5] The plasma processing apparatus of E1 or E2, wherein the at least one first conductor protrudes from the upper conductor toward an inside of the chamber, and
   wherein the at least one second conductor protrudes from the lower conductor toward the inside of the chamber.
[E6] The plasma processing apparatus of any one of E1 to E5, further including: an exhaust duct including the upper conductor and the lower conductor.
[E7] The plasma processing apparatus of E6, wherein the exhaust duct constitutes the choke.
[E8] The plasma processing apparatus of E7, wherein the dielectric member protrudes into the exhaust duct.
[E9] The plasma processing apparatus of any one of E1 to E8, wherein the length of the gap is equal to or less than two times a thickness of a plasma sheath.
[E10] The plasma processing apparatus of any one of E1 to E9, wherein the at least one first conductor includes a plurality of first conductors arranged at equal intervals along a circumferential direction,
   wherein the at least one second conductor includes a plurality of second conductors arranged at equal intervals along the circumferential direction, and
   wherein the plurality of second conductors extend below corresponding first conductors among the plurality of first conductors.

According to the present disclosure in some embodiments, it is possible to ignite plasma even when electromagnetic waves are highly reflected.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus, comprising:
a chamber including an inner wall surface;
an introduction portion configured to introduce electromagnetic waves for plasma generation into the chamber;
a choke configured to suppress the electromagnetic waves from propagating downward along the inner wall surface, and including a dielectric member, an upper conductor including a portion of the inner wall surface and extending above the dielectric member, and a lower conductor extending below the dielectric member;
at least one first conductor electrically connected to the upper conductor; and
at least one second conductor electrically connected to the lower conductor and extending below the at least one first conductor,
wherein the at least one first conductor and the at least one second conductor provide a gap between the at least one first conductor and the at least one second conductor at a location along an inner end of the dielectric member, the gap having a length in a vertical direction shorter than a thickness of the dielectric member.

2. The plasma processing apparatus of claim 1, wherein the dielectric member includes a first portion extending along the gap and a second portion other than the first portion, and
wherein an inner end of the second portion is continuous with each of an inner surface of the upper conductor and an inner surface of the lower conductor, and constitutes a portion of the inner wall surface.

3. The plasma processing apparatus of claim 2, wherein an inner end of the first portion extends further outward relative to a center of the chamber compared to the inner end of the second portion.

4. The plasma processing apparatus of claim 3, wherein the at least one first conductor is a portion of the upper conductor, and
wherein the at least one second conductor is a portion of the lower conductor.

5. The plasma processing apparatus of claim 3, further comprising:
an exhaust duct including the upper conductor and the lower conductor.

6. The plasma processing apparatus of claim 3, wherein the length of the gap is equal to or less than two times a thickness of a plasma sheath.

7. The plasma processing apparatus of claim 3, wherein the at least one first conductor includes a plurality of first conductors arranged at equal intervals along a circumferential direction,
wherein the at least one second conductor includes a plurality of second conductors arranged at equal intervals along the circumferential direction, and
wherein the plurality of second conductors extend below corresponding first conductors among the plurality of first conductors.

8. The plasma processing apparatus of claim 1, wherein the at least one first conductor protrudes from the upper conductor toward an inside of the chamber, and
wherein the at least one second conductor protrudes from the lower conductor toward the inside of the chamber.

9. The plasma processing apparatus of claim 2, wherein the at least one first conductor protrudes from the upper conductor toward an inside of the chamber, and
wherein the at least one second conductor protrudes from the lower conductor toward the inside of the chamber.

10. The plasma processing apparatus of claim 9, further comprising:
an exhaust duct including the upper conductor and the lower conductor.

11. The plasma processing apparatus of claim 10, wherein the exhaust duct constitutes the choke.

12. The plasma processing apparatus of claim 11, wherein the dielectric member protrudes into the exhaust duct.

13. The plasma processing apparatus of claim 9, wherein the length of the gap is equal to or less than two times a thickness of a plasma sheath.

14. The plasma processing apparatus of claim 9, wherein the at least one first conductor includes a plurality of first conductors arranged at equal intervals along a circumferential direction,
wherein the at least one second conductor includes a plurality of second conductors arranged at equal intervals along the circumferential direction, and
wherein the plurality of second conductors extend below corresponding first conductors among the plurality of first conductors.

15. The plasma processing apparatus of claim 1, wherein the at least one first conductor is a portion of the upper conductor, and
wherein the at least one second conductor is a portion of the lower conductor.

16. The plasma processing apparatus of claim 1, further comprising:
an exhaust duct including the upper conductor and the lower conductor.

17. The plasma processing apparatus of claim 1, wherein the length of the gap is equal to or less than two times a thickness of a plasma sheath.

18. The plasma processing apparatus of claim 1, wherein the at least one first conductor includes a plurality of first conductors arranged at equal intervals along a circumferential direction,
wherein the at least one second conductor includes a plurality of second conductors arranged at equal intervals along the circumferential direction, and
wherein the plurality of second conductors extend below corresponding first conductors among the plurality of first conductors.
